(19) United States
(12) Patent Application Publication
(10) Pub. No.: US 2016/0351151 A1
(43) Pub. Date: Dec. 1, 2016

(54) TFT ARRAY SUBSTRATE

(71) Applicant: Shenzhen China Star Optoelectronics Technology Co. Ltd., Shenzhen City (CN)

(72) Inventor: Shangcao Cao, Shenzhen City (CN)

(21) Appl. No.: 14/771,205

(22) PCT Filed: Jun. 18, 2015
(86) PCT No.: PCT/CN2015/081723

§ 371 Date: Aug. 28, 2015

(30) Foreign Application Priority Data
May 7, 2015 (CN) 201510230459.5

(51) Int. Cl. G09G 3/36; H01L 27/12; G02F 1/1343; G02F 1/1362; G02F 1/1368

(52) U.S. Cl. CPC G09G 3/3677; G09G 3/3688; G02F 1/136286; G02F 1/1368; G02F 1/134336; H01L 27/124; G09G 2320/0242; G09G 2300/0452; G09G 2310/0251; G09G 2320/0247; G02F 2001/134345

(57) ABSTRACT

The present invention provides a TFT array substrate, in comparison with the TFT array substrate utilizing 2D1G technology according to prior art, the amount of the scan lines is increased to diminish the amount of the data lines. The data lines are categorized into main data lines (MD) and sub data lines (SD), and the main data lines (MD) control main areas of the sub pixels at their two sides, and the sub data lines (SD) control sub areas of the sub pixels at their two sides. Meanwhile, two GOA drive circuit respectively positioned at left, right two sides of the display area perform dual side drive to all the scan lines. Accordingly, the color shift issue of VA type liquid crystal display can be improved, and the charge efficiency can be ensured to decrease the cost of the liquid crystal panel.

### FIELD OF THE INVENTION

The present invention relates to a display technology field, and more particularly to a TFT array substrate.

### BACKGROUND OF THE INVENTION

The Liquid Crystal Display (LCD) possesses advantages of thin body, power saving and no radiation to be widely used in many application scope. Such as LCD TV, mobile phone, personal digital assistant (PDA), digital camera, notebook, laptop, and dominates the flat panel display field.

Generally, the liquid crystal display panel comprises a Color Filter (CF), a Thin Film Transistor Array Substrate (TFT Array Substrate) and a Liquid Crystal Layer positioned between the two substrates. Meanwhile, pixel electrodes, common electrodes are provided respectively at relative inner sides of the two substrates. The light of back light module is reflected to generate images by applying voltages to control the liquid crystal molecules to be changed directions. On the TFT array substrate, a plurality of R, G and B sub pixels aligned in array, a plurality of scan lines and a plurality of data lines are formed. Each sub pixel receives the scan signal through the corresponding scan line, and receives the data signal through the corresponding data line for showing images.

For the LCD in the mainstream market, three types, which respectively are Twisted Nematic (TN), Super Twisted Nematic (STN), In-Plane Switching (IPS) and Vertical Alignment (VA) can be illustrated. The VA liquid crystal display panel possesses extremely high contrast than the liquid crystal display panels of other types. It has very wide application in large scale display, such as television or etc. However, because the VA liquid crystal display utilizes vertical twist liquid crystals and the birefraction difference of the liquid crystal molecules is larger, the issue of the color shift under large view angle is more serious. Thus, the brightness difference of the VA liquid crystal display from different angles is larger and as a result, the image distortion occurs.

2D1G, 2G1D or the resistance divider technology is the common skill for solving the color shift issue of the VA liquid crystal display. Please refer to FIG. 1, which is a TFT array substrate utilizing 2D1G technology according to prior art, comprising a plurality of sub pixels arranged in array, and each sub pixel is divided into a main area and a sub area; the main area of each sub pixel is connected to a main area TFT, and the sub area of each sub pixel is connected to a sub area TFT, and in accordance with sub pixels of each row, a scan line Gate is provided, and in accordance with sub pixels of each column, the sub area data line and the main area data line respectively positioned at the left, right two sides are provided. The sub area data line provides a sub data signal Sdata to the sub area Sub through the sub area TFT, and the main area data line provides a main data signal Mdata to the main area Main through the main area TFT. As shown in FIG. 2, the voltage difference between the main data signal Mdata and the common voltage COM is larger than the voltage difference between the sub data signal Sdata and the common voltage COM to make the charge ratios of the main area and the sub area be different. Thus, the color reducibility under different vie angles can be promoted to improve the color shift.

Although, the TFT array substrate utilizing 2D1G technology according to prior art can improve the color shift, such design requires to double the amount of the data lines. Not only the cost of the drive IC increase but the Fanout area will become crowded to intensify the RC delay, to reduce the charge efficiency and to affect the competitiveness of the productions.

### SUMMARY OF THE INVENTION

An objective of the present invention is to provide a TFT array substrate capable of improving the color shift issue of VA type liquid crystal display and reducing the manufacture cost of the liquid crystal display panel under the premise without increasing the amounts of the data signal lines.

For realizing the aforesaid objective, the present invention provides a TFT array substrate, comprising: a display area and a non display area;

the display area comprises:

a plurality of data lines, which are mutually parallel, sequentially aligned and vertical, a plurality of scan lines, which are mutually parallel, sequentially aligned and horizontal and a plurality of sub pixels arranged in array;

each sub pixel is divided into a main area and a sub area; the main area of each sub pixel is connected to a main area TFT, and the sub area of each sub pixel is connected to a sub area TFT;

in accordance with sub pixels of each row, an upper scan line and a lower scan line are respectively provided at upper, lower sides of sub pixels of the row;

in accordance with sub pixels of every two adjacent columns, a data line is provided between the sub pixels of two adjacent columns; the data lines comprise: main data lines and sub data lines, and the main data lines and the sub data lines are alternately aligned in sequence along the horizontal direction; the main areas of respective sub pixels at two sides of each main data line are electrically coupled to the main data line with the corresponding main area TFTs, and the sub areas of respective sub pixels at two sides of each sub data line are electrically coupled to the sub data line with the corresponding sub area TFTs;

the non display area comprises:

a source driver positioned above the display area, a first GOA drive circuit and a second GOA drive circuit respectively positioned at left, right two sides of the display area;

the source driver generates main data signals and sub data signals and correspondingly transmits the same to the main data lines and the sub data lines;

the first GOA drive circuit and the second GOA drive circuit perform dual side drive to all the scan lines respectively at the left, right two sides of the display area.

In the sub pixels of the same row, a gate of the main area TFT corresponding to each sub pixel is coupled to the upper scan line or the lower scan line, and a gate of the sub area TFT is coupled to the other scan line which is not the scan line coupled with the gate of the main area TFT.

In the sub pixels of the same row, alignments of the sub pixels of every two adjacent columns are the same, of which both are that the main areas are positioned above the sub areas, or that the sub areas are positioned above the main areas.

In the sub pixels of the same row, alignments of the sub pixels of every two adjacent columns are different, of which in the sub pixels of one column, the main areas are positioned above the sub areas, and in the sub pixels of the other column, the sub areas are positioned above the main areas.

In the sub pixels of the same row, in two main area TFTs correspondingly coupled to main areas of the sub pixels of every two adjacent columns, wherein a gate of one main area TFT is coupled to the upper scan line corresponding to the sub pixels of the row, and a gate of the other main area TFT is coupled to the lower scan line corresponding to the sub pixels of the row.

In the sub pixels of the same row, in the sub pixels of which the main areas are positioned above the sub areas, the gates of the corresponding main area TFTs are coupled to the upper scan line corresponding to the sub pixels of the row; in the sub pixels of which the sub areas are positioned above the main areas, the gates of the corresponding main area TFTs are coupled to the lower scan line corresponding to the sub pixels of the row.

The plurality of sub pixels arranged in array comprise: red sub pixels, green sub pixels and blue sub pixels are alternately aligned in sequence along the horizontal direction.

In the sub pixels of the same row, all the gates of the main area TFTs coupled to the red sub pixel main areas are coupled to the upper scan line corresponding to the sub pixels of the row, and all the gates of the sub area TFTs coupled to the red sub pixel sub areas are coupled to the upper scan line corresponding to the sub pixels of the row, and all the gates of the main area TFTs coupled to the green sub pixel main areas are coupled to the lower scan line corresponding to the sub pixels of the row, and all the gates of the sub area TFTs coupled to the green sub pixel sub areas are coupled to the lower scan line corresponding to the sub pixels of the row so that the red sub pixels are charged before the green sub pixels.

In the sub pixels of the same row, all the gates of the main area TFTs coupled to the green sub pixel main areas are coupled to the upper scan line corresponding to the sub pixels of the row, and all the gates of the sub area TFTs coupled to the green sub pixel sub areas are coupled to the upper scan line corresponding to the sub pixels of the row, and all the gates of the main area TFTs coupled to the red sub pixel main areas are coupled to the lower scan line corresponding to the sub pixels of the row, and all the gates of the sub area TFTs coupled to the red sub pixel sub areas are coupled to the lower scan line corresponding to the sub pixels of the row so that the green sub pixels are charged before the red sub pixels.

A voltage difference between the main data signal and a common voltage is larger than a voltage difference between the sub data signal and the common voltage.

The present invention further provides a TFT array substrate, comprising: a display area and a non display area;

the display area comprises:

a plurality of data lines, which are mutually parallel, sequentially aligned and vertical, a plurality of scan lines, which are mutually parallel, sequentially aligned and horizontal and a plurality of sub pixels arranged in array;

each sub pixel is divided into a main area and a sub area; the main area of each sub pixel is connected to a main area TFT, and the sub area of each sub pixel is connected to a sub area TFT;

in accordance with sub pixels of each row, an upper scan line and a lower scan line are respectively provided at upper, lower sides of sub pixels of the row;

in accordance with sub pixels of every two adjacent columns, a data line is provided between the sub pixels of two adjacent columns; the data lines comprise: main data lines and sub data lines, and the main data lines and the sub data lines are alternately aligned in sequence along the horizontal direction; the main areas of respective sub pixels at two sides of each main data line are electrically coupled to the main data line with the corresponding main area TFTs, and the sub areas of respective sub pixels at two sides of each sub data line are electrically coupled to the sub data line with the corresponding sub area TFTs;

the non display area comprises:

a source driver positioned above the display area, a first GOA drive circuit and a second GOA drive circuit respectively positioned at left, right two sides of the display area;

the source driver generates main data signals and sub data signals and correspondingly transmits the same to the main data lines and the sub data lines;

the first GOA drive circuit and the second GOA drive circuit perform dual side drive to all the scan lines respectively at the left, right two sides of the display area;

wherein in the sub pixels of the same row, a gate of the main area TFT corresponding to each sub pixel is coupled to the upper scan line or the lower scan line, and a gate of the sub area TFT is coupled to the other scan line which is not the scan line coupled with the gate of the main area TFT;

wherein the plurality of sub pixels arranged in array comprise: red sub pixels, green sub pixels and blue sub pixels are alternately aligned in sequence along the horizontal direction;

wherein a voltage difference between the main data signal and a common voltage is larger than a voltage difference between the sub data signal and the common voltage.

The benefits of the present invention are: the present invention provides a TFT array substrate, and in comparison with the TFT array substrate utilizing 2D1G technology according to prior art, the amount of the scan lines is increased to diminish the amount of the data lines. The data lines are categorized into main data lines and sub data lines, and the main data lines control main areas of the sub pixels at their two sides, and the sub data lines control sub areas of the sub pixels at their two sides. Meanwhile, two GOA drive circuit respectively positioned at left, right two sides of the display area perform dual side drive to all the scan lines. Accordingly, the color shift issue of VA type liquid crystal display can be improved, and the charge efficiency can be ensured to decrease the cost of the liquid crystal panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of a TFT array substrate utilizing 2D1G technology according to prior art;

FIG. 2 is a waveform diagram corresponding to main and sub data signals in FIG. 1;

FIG. 3 is a structural diagram of a TFT array substrate structure according to the present invention;

FIG. 4 is a diagram of a display area of a TFT array substrate according to the first embodiment of the present invention;

FIG. 5 is a diagram of a display area of a TFT array substrate according to the second embodiment of the present invention;

FIG. 6 is a diagram of a display area of a TFT array substrate according to the third embodiment of the present invention;

FIG. 7 is a diagram of a display area of a TFT array substrate according to the fourth embodiment of the present invention.

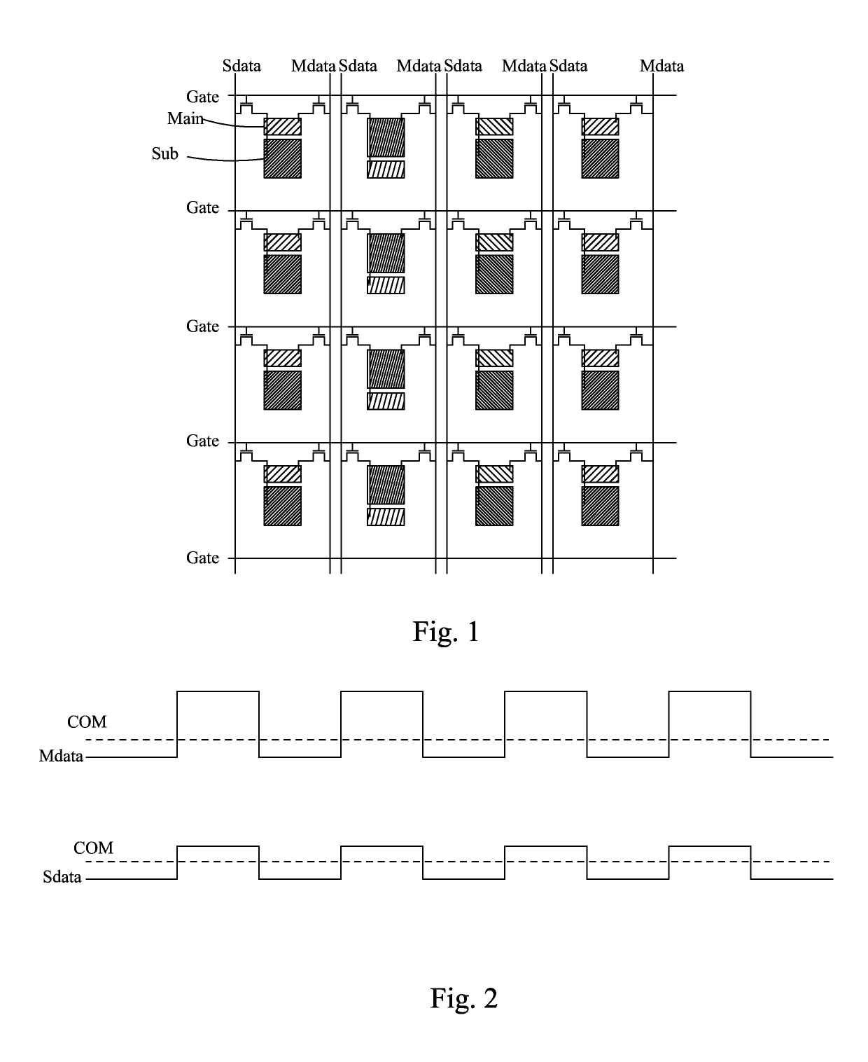

### DETAILED DESCRIPTION OF PREFERRED EMBODIMENTS

For better explaining the technical solution and the effect of the present invention, the present invention will be further described in detail with the accompanying drawings and the specific embodiments.

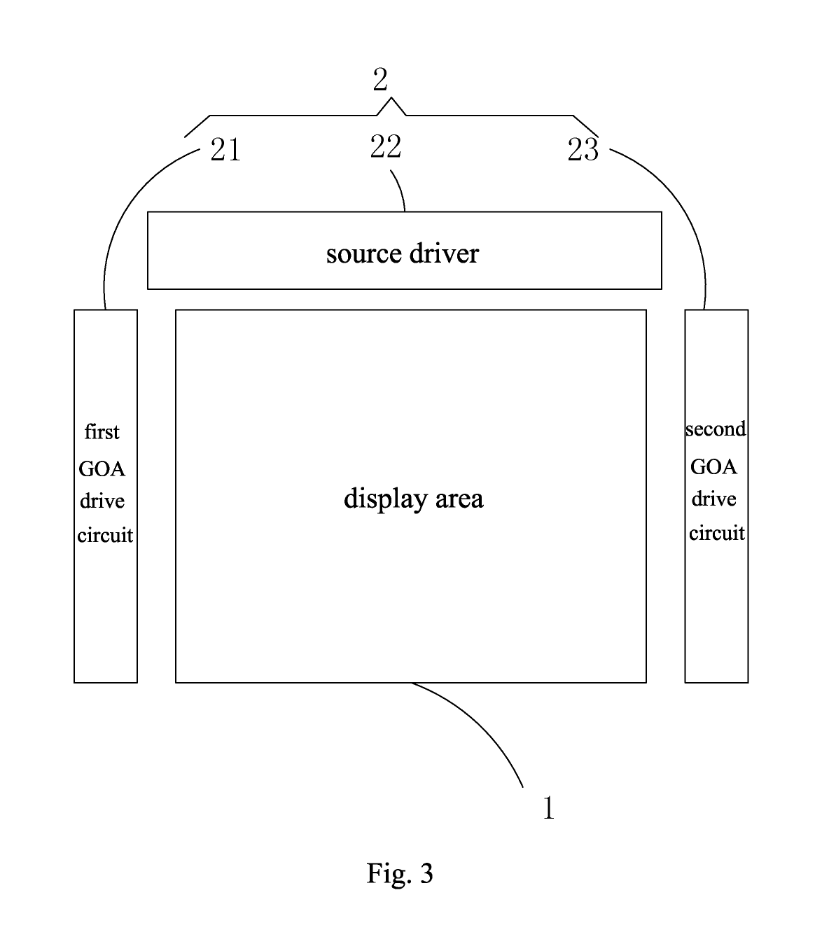

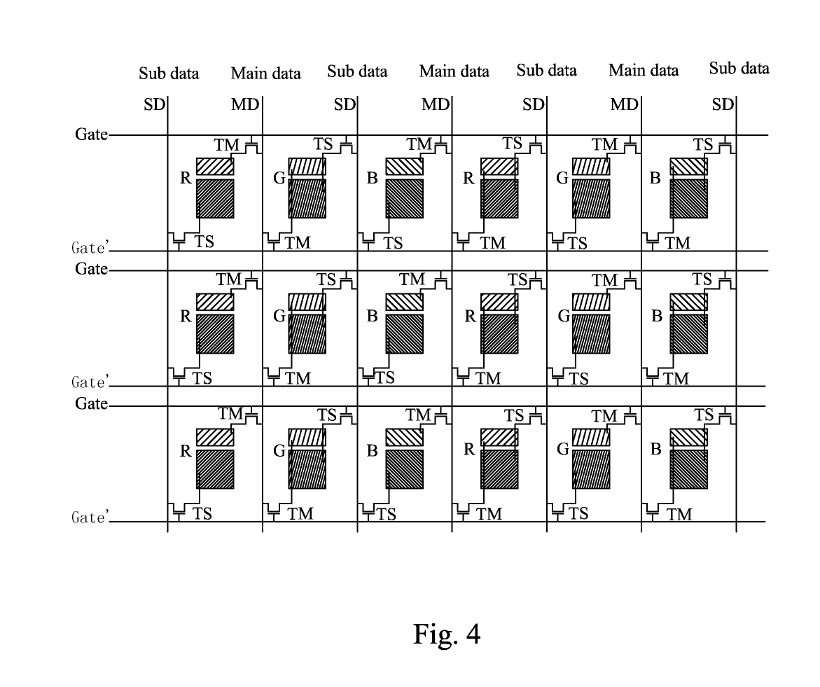

The present invention provides a TFT array substrate. Please refer to FIG. 3 in combination with FIG. 4, which is the first embodiment of the present invention. The TFT array substrate comprises: a display area 1 and a non display area 2 positioned around the display area 1.

The display area 1 comprises: a plurality of data lines, which are mutually parallel, sequentially aligned and vertical, a plurality of scan lines, which are mutually parallel, sequentially aligned and horizontal and a plurality of sub pixels arranged in array.

Each sub pixel is divided into a main area (indicated with a smaller rectangular) and a sub area (indicated with a larger rectangular); the main area of each sub pixel is connected to a main area TFT TM, and the sub area of each sub pixel is connected to a sub area TFT TS. In the first embodiment shown in FIG. 4, in the sub pixels of the same row, alignments of the sub pixels of every two adjacent columns are the same, of which both are that the main areas are positioned above the sub areas, and alternatively, both are that the sub areas are positioned above the main areas (not shown).

In accordance with sub pixels of each row, an upper scan line Gate and a lower scan line Gate′ are respectively provided at upper, lower sides of sub pixels of the row. The upper scan line Gate controls the main area TFT TM and the sub area TFT TS correspondingly coupled thereto, and the lower scan line Gate′ controls the main area TFT TM and the sub area TFT TS correspondingly coupled thereto.

In accordance with sub pixels of every two adjacent columns, a data line is provided between the sub pixels of two adjacent columns; the data lines comprise: main data lines MD and sub data lines SD, and the main data lines MD and the sub data lines SD are alternately aligned in sequence along the horizontal direction; the main areas of respective sub pixels at two sides of each main data line MD are electrically coupled to the main data line MD with the corresponding main area TFTs TM, and the sub areas of respective sub pixels at two sides of each sub data line SD are electrically coupled to the sub data line SD with the corresponding sub area TFTs TS. In the first embodiment shown in FIG. 4, in the sub pixels of the same row, a gate of the main area TFT TM corresponding to each sub pixel is coupled to the upper scan line Gate or the lower scan line Gate′, and a gate of the sub area TFT TS is coupled to the other scan line which is not the scan line coupled with the gate of the main area TFT TM. Furthermore, in the sub pixels of the same row, in two main area TFTs TM correspondingly coupled to main areas of the sub pixels of every two adjacent columns, wherein a gate of one main area TFT TM is coupled to the upper scan line Gate corresponding to the sub pixels of the row, and a gate of the other main area TFT TM is coupled to the lower scan line Gate′ corresponding to the sub pixels of the row. For example, in the sub pixel of the first row, first column in FIG. 4, the gate of the main area TFT TM corresponding thereto is coupled to the upper scan line Gate, and the gate of the sub area TFT TS is coupled to the lower scan line Gate′, and in the sub pixel of the first row, second column in FIG. 4, the gate of the main area TFT TM corresponding thereto is coupled to the lower scan line Gate′, and the gate of the sub area TFT TS is coupled to the upper scan line Gate.

The non display area 2 comprises: a source driver 22 positioned above the display area 1, a first GOA drive circuit 21 and a second GOA drive circuit 23 respectively positioned at left, right two sides of the display area 1.

The source driver 22 generates main data signals Main data and sub data signals Sub data and correspondingly transmits the same to the main data lines MD and the sub data lines SD. For making the charge ratios of the main areas and the sub areas of respective sub pixels be different, as shown in FIG. 2, a voltage difference between the main data signal Main data and a common voltage is larger than a voltage difference between the sub data signal Sub data and the common voltage.

The first GOA drive circuit 21 and the second GOA drive circuit 23 perform dual side drive to all the scan lines respectively at the left, right two sides of the display area 1. Namely, the first GOA drive circuit 21 performs drive to all the scan lines from left to right. In the mean time, the second GOA drive circuit 23 performs drive to all the scan lines from right to left.

In comparison with the TFT array substrate utilizing 2D1G technology according to prior art, the TFT array substrate of the present invention increases the amount of the scan lines to diminish the amount of the data lines. The data lines are categorized into main data lines MD and sub data lines SD, and the main data lines MD control main areas of the sub pixels at their two sides, and the sub data lines SD control sub areas of the sub pixels at their two sides. Meanwhile, the first GOA drive circuit 21 and the second GOA drive circuit 23 respectively positioned at left, right two sides of the display area 1 perform dual side drive to all the scan lines. Accordingly, the color shift issue of VA type liquid crystal display can be improved, and the charge efficiency can be ensured to decrease the cost of the liquid crystal panel.

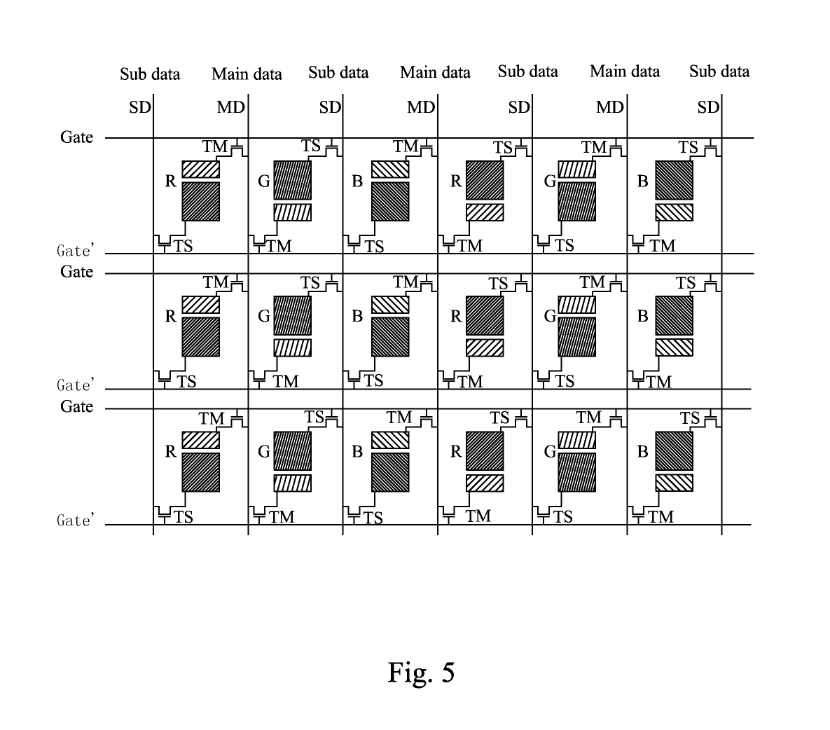

Please refer to FIG. 5. FIG. 5 is a display area 1 of a TFT array substrate according to the second embodiment of the present invention. The difference of the second embodiment from the first embodiment is that in the sub pixels of the same row, alignments of the sub pixels of every two adjacent columns are different, of which in the sub pixels of one column, the main areas are positioned above the sub areas, and in the sub pixels of the other column, the sub areas are positioned above the main areas. In the sub pixels of which the main areas are positioned above the sub areas, the gates of the corresponding main area TFTs TM are coupled to the upper scan line Gate corresponding to the sub pixels of the row, and the gates of the corresponding sub area TFTs TS are coupled to the lower scan line Gate′ corresponding to the sub pixels of the row; in the sub pixels of which the sub areas are positioned above the main areas, the gates of the corresponding main area TFTs TM are coupled to the lower scan line Gate′ corresponding to the sub pixels of the row, and the gates of the corresponding sub area TFTs TS are coupled to the upper scan line Gate corresponding to the sub pixels of the row. In comparison with the first embodiment, the advantage of the second embodiment is that the leads among the respective main area TFTs, the sub area TFTs and corresponding main areas and sub areas are the shortest. Under circumstance that the resolution is higher, such flexible alignment will not cause the abnormality of the images, and can raise the aperture ratio and reduce the RC delay. The reset is the same as the first embodiment. The repeated description is omitted here.

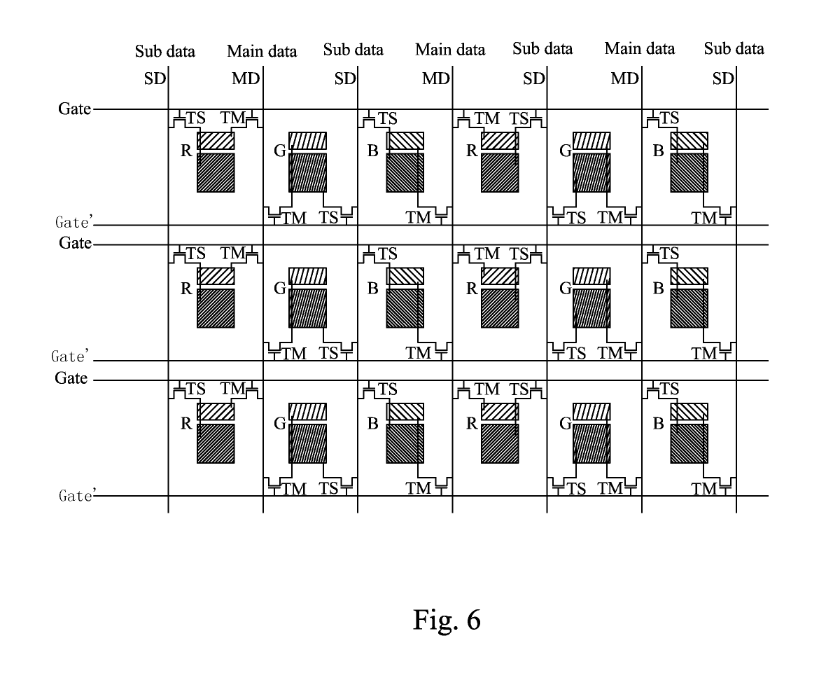

Please refer to FIG. 6. FIG. 6 is a display area 1 of a TFT array substrate according to the third embodiment of the present invention: the plurality of sub pixels arranged in array comprise: red sub pixels R, green sub pixels G and blue sub pixels B are alternately aligned in sequence along the horizontal direction. In the sub pixels of the same row, all the gates of the main area TFTs TM coupled to the red sub pixel R main areas are coupled to the upper scan line Gate corresponding to the sub pixels of the row, and all the gates of the sub area TFTs TS coupled to the red sub pixel R sub areas are coupled to the upper scan line Gate corresponding to the sub pixels of the row, and all the gates of the main area TFTs TM coupled to the green sub pixel G main areas are coupled to the lower scan line Gate′ corresponding to the sub pixels of the row, and all the gates of the sub area TFTs TS coupled to the green sub pixel G sub areas are coupled to the lower scan line Gate′ corresponding to the sub pixels of the row. The first GOA drive circuit 21 and the second GOA drive circuit 23 perform dual side drive to all the scan lines according to the sequence from top to bottom so that the red sub pixels R are charged before the green sub pixels G. The reset is the same as the first embodiment. The repeated description is omitted here. The third embodiment is applicable for the pre-charge TFT array substrate and can reduce the flickers.

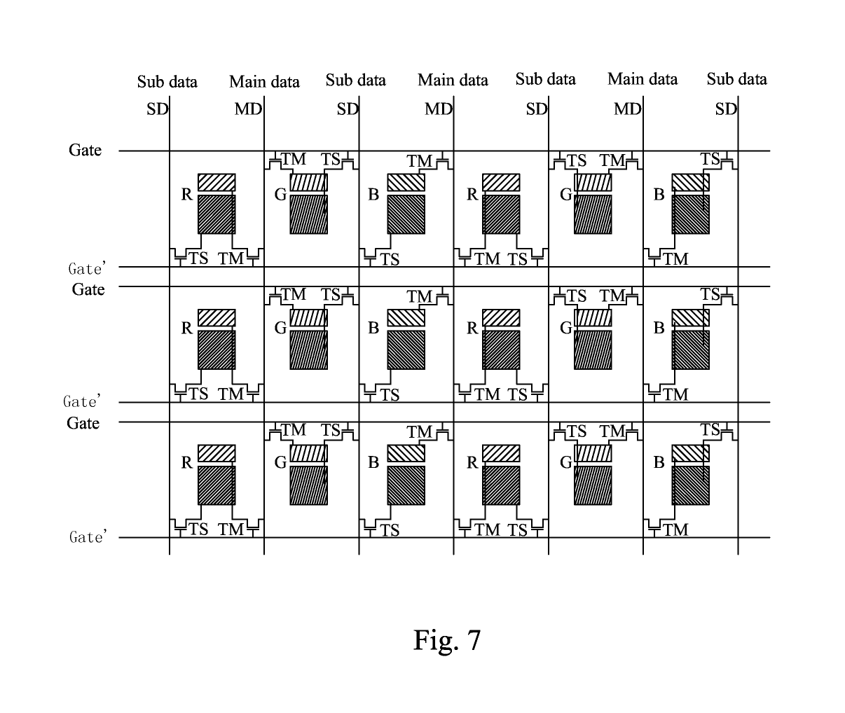

Please refer to FIG. 7. FIG. 7 is a display area 1 of a TFT array substrate according to the fourth embodiment of the present invention. The difference from the third embodiment is that in the sub pixels of the same row, all the gates of the main area TFTs TM coupled to the green sub pixel G main areas are coupled to the upper scan line Gate corresponding to the sub pixels of the row, and all the gates of the sub area TFTs TS coupled to the green sub pixel G sub areas are coupled to the upper scan line Gate corresponding to the sub pixels of the row, and all the gates of the main area TFTs TM coupled to the red sub pixel R main areas are coupled to the lower scan line Gate′ corresponding to the sub pixels of the row, and all the gates of the sub area TFTs TS coupled to the red sub pixel R sub areas are coupled to the lower scan line Gate′ corresponding to the sub pixels of the row. The first GOA drive circuit 21 and the second GOA drive circuit 23 perform dual side drive to all the scan lines according to the sequence from top to bottom so that the green sub pixels G are charged before the red sub pixels R. The fourth embodiment is similarly applicable for the pre-charge TFT array substrate and can reduce the flickers.

The selections of the third, fourth embodiments can be determined according to the adjustment of the optical density (OD) of the color resist material or programmable gamma calibration buffer circuit chip (P-gamma).

In conclusion, in comparison with the TFT array substrate utilizing 2D1G technology according to prior art, the amount of the scan lines is increased to diminish the amount of the data lines. The data lines are categorized into main data lines and sub data lines, and the main data lines control main areas of the sub pixels at their two sides, and the sub data lines control sub areas of the sub pixels at their two sides. Meanwhile, two GOA drive circuit respectively positioned at left, right two sides of the display area perform dual side drive to all the scan lines. Accordingly, the color shift issue of VA type liquid crystal display can be improved, and the charge efficiency can be ensured to decrease the cost of the liquid crystal panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A TFT array substrate, comprising: a display area and a non display area;
the display area comprises:
a plurality of data lines, which are mutually parallel, sequentially aligned and vertical, a plurality of scan lines, which are mutually parallel, sequentially aligned and horizontal and a plurality of sub pixels arranged in array;
each sub pixel is divided into a main area and a sub area; the main area of each sub pixel is connected to a main area TFT, and the sub area of each sub pixel is connected to a sub area TFT;
in accordance with sub pixels of each row, an upper scan line and a lower scan line are respectively provided at upper, lower sides of sub pixels of the row;
in accordance with sub pixels of every two adjacent columns, a data line is provided between the sub pixels of two adjacent columns; the data lines comprise: main data lines and sub data lines, and the main data lines and the sub data lines are alternately aligned in sequence along the horizontal direction; the main areas of respective sub pixels at two sides of each main data line are electrically coupled to the main data line with the corresponding main area TFTs, and the sub areas of respective sub pixels at two sides of each sub data line are electrically coupled to the sub data line with the corresponding sub area TFTs;
the non display area comprises:
a source driver positioned above the display area, a first GOA drive circuit and a second GOA drive circuit respectively positioned at left, right two sides of the display area;
the source driver generates main data signals and sub data signals and correspondingly transmits the same to the main data lines and the sub data lines;
the first GOA drive circuit and the second GOA drive circuit perform dual side drive to all the scan lines respectively at the left, right two sides of the display area.

2. The TFT array substrate according to claim 1, wherein in the sub pixels of the same row, a gate of the main area TFT corresponding to each sub pixel is coupled to the upper scan line or the lower scan line, and a gate of the sub area TFT is coupled to the other scan line which is not the scan line coupled with the gate of the main area TFT.

3. The TFT array substrate according to claim 2, wherein in the sub pixels of the same row, alignments of the sub pixels of every two adjacent columns are the same, of which both are that the main areas are positioned above the sub areas, or that the sub areas are positioned above the main areas.

4. The TFT array substrate according to claim 2, wherein in the sub pixels of the same row, alignments of the sub pixels of every two adjacent columns are different, of which in the sub pixels of one column, the main areas are positioned above the sub areas, and in the sub pixels of the other column, the sub areas are positioned above the main areas.

5. The TFT array substrate according to claim 3, wherein in the sub pixels of the same row, in two main area TFTs correspondingly coupled to main areas of the sub pixels of every two adjacent columns, wherein a gate of one main area TFT is coupled to the upper scan line corresponding to the sub pixels of the row, and a gate of the other main area TFT is coupled to the lower scan line corresponding to the sub pixels of the row.

6. The TFT array substrate according to claim 4, wherein in the sub pixels of the same row, in the sub pixels of which the main areas are positioned above the sub areas, the gates of the corresponding main area TFTs are coupled to the upper scan line corresponding to the sub pixels of the row; in the sub pixels of which the sub areas are positioned above the main areas, the gates of the corresponding main area TFTs are coupled to the lower scan line corresponding to the sub pixels of the row.

7. The TFT array substrate according to claim 1, wherein the plurality of sub pixels arranged in array comprise: red sub pixels, green sub pixels and blue sub pixels are alternately aligned in sequence along the horizontal direction.

8. The TFT array substrate according to claim 7, wherein in the sub pixels of the same row, all the gates of the main area TFTs coupled to the red sub pixel main areas are coupled to the upper scan line corresponding to the sub pixels of the row, and all the gates of the sub area TFTs coupled to the red sub pixel sub areas are coupled to the upper scan line corresponding to the sub pixels of the row, and all the gates of the main area TFTs coupled to the green sub pixel main areas are coupled to the lower scan line corresponding to the sub pixels of the row, and all the gates of the sub area TFTs coupled to the green sub pixel sub areas are coupled to the lower scan line corresponding to the sub pixels of the row so that the red sub pixels are charged before the green sub pixels.

9. The TFT array substrate according to claim 7, wherein in the sub pixels of the same row, all the gates of the main area TFTs coupled to the green sub pixel main areas are coupled to the upper scan line corresponding to the sub pixels of the row, and all the gates of the sub area TFTs coupled to the green sub pixel sub areas are coupled to the upper scan line corresponding to the sub pixels of the row, and all the gates of the main area TFTs coupled to the red sub pixel main areas are coupled to the lower scan line corresponding to the sub pixels of the row, and all the gates of the sub area TFTs coupled to the red sub pixel sub areas are coupled to the lower scan line corresponding to the sub pixels of the row so that the green sub pixels are charged before the red sub pixels.

10. The TFT array substrate according to claim 1, wherein a voltage difference between the main data signal and a common voltage is larger than a voltage difference between the sub data signal and the common voltage.

11. A TFT array substrate, comprising: a display area and a non display area;
the display area comprises:
a plurality of data lines, which are mutually parallel, sequentially aligned and vertical, a plurality of scan lines, which are mutually parallel, sequentially aligned and horizontal and a plurality of sub pixels arranged in array;
each sub pixel is divided into a main area and a sub area; the main area of each sub pixel is connected to a main area TFT, and the sub area of each sub pixel is connected to a sub area TFT;
in accordance with sub pixels of each row, an upper scan line and a lower scan line are respectively provided at upper, lower sides of sub pixels of the row;
in accordance with sub pixels of every two adjacent columns, a data line is provided between the sub pixels of two adjacent columns; the data lines comprise: main data lines and sub data lines, and the main data lines and the sub data lines are alternately aligned in sequence along the horizontal direction; the main areas of respective sub pixels at two sides of each main data line are electrically coupled to the main data line with the corresponding main area TFTs, and the sub areas of respective sub pixels at two sides of each sub data line are electrically coupled to the sub data line with the corresponding sub area TFTs;
the non display area comprises:
a source driver positioned above the display area, a first GOA drive circuit and a second GOA drive circuit respectively positioned at left, right two sides of the display area;
the source driver generates main data signals and sub data signals and correspondingly transmits the same to the main data lines and the sub data lines;
the first GOA drive circuit and the second GOA drive circuit perform dual side drive to all the scan lines respectively at the left, right two sides of the display area;
wherein in the sub pixels of the same row, a gate of the main area TFT corresponding to each sub pixel is coupled to the upper scan line or the lower scan line, and a gate of the sub area TFT is coupled to the other scan line which is not the scan line coupled with the gate of the main area TFT;
wherein the plurality of sub pixels arranged in array comprise: red sub pixels, green sub pixels and blue sub pixels are alternately aligned in sequence along the horizontal direction;
wherein a voltage difference between the main data signal and a common voltage is larger than a voltage difference between the sub data signal and the common voltage.

12. The TFT array substrate according to claim 11, wherein in the sub pixels of the same row, alignments of the sub pixels of every two adjacent columns are the same, of which both are that the main areas are positioned above the sub areas, or that the sub areas are positioned above the main areas.

13. The TFT array substrate according to claim 11, wherein in the sub pixels of the same row, alignments of the sub pixels of every two adjacent columns are different, of which in the sub pixels of one column, the main areas are positioned above the sub areas, and in the sub pixels of the other column, the sub areas are positioned above the main areas.

14. The TFT array substrate according to claim 12, wherein in the sub pixels of the same row, in two main area TFTs correspondingly coupled to main areas of the sub pixels of every two adjacent columns, wherein a gate of one main area TFT is coupled to the upper scan line corresponding to the sub pixels of the row, and a gate of the other main area TFT is coupled to the lower scan line corresponding to the sub pixels of the row.

15. The TFT array substrate according to claim 13, wherein in the sub pixels of the same row, in the sub pixels of which the main areas are positioned above the sub areas, the gates of the corresponding main area TFTs are coupled to the upper scan line corresponding to the sub pixels of the row; in the sub pixels of which the sub areas are positioned above the main areas, the gates of the corresponding main area TFTs are coupled to the lower scan line corresponding to the sub pixels of the row.

16. The TFT array substrate according to claim 11, wherein in the sub pixels of the same row, all the gates of the main area TFTs coupled to the red sub pixel main areas are coupled to the upper scan line corresponding to the sub pixels of the row, and all the gates of the sub area TFTs coupled to the red sub pixel sub areas are coupled to the upper scan line corresponding to the sub pixels of the row, and all the gates of the main area TFTs coupled to the green sub pixel main areas are coupled to the lower scan line corresponding to the sub pixels of the row, and all the gates of the sub area TFTs coupled to the green sub pixel sub areas are coupled to the lower scan line corresponding to the sub pixels of the row so that the red sub pixels are charged before the green sub pixels.

17. The TFT array substrate according to claim 11, wherein in the sub pixels of the same row, all the gates of the main area TFTs coupled to the green sub pixel main areas are coupled to the upper scan line corresponding to the sub pixels of the row, and all the gates of the sub area TFTs coupled to the green sub pixel sub areas are coupled to the upper scan line corresponding to the sub pixels of the row, and all the gates of the main area TFTs coupled to the red sub pixel main areas are coupled to the lower scan line corresponding to the sub pixels of the row, and all the gates of the sub area TFTs coupled to the red sub pixel sub areas are coupled to the lower scan line corresponding to the sub pixels of the row so that the green sub pixels are charged before the red sub pixels.
